(19) United States
(12) Patent Application Publication
(10) Pub. No.: US 2024/0320401 A1
(43) Pub. Date: Sep. 26, 2024

(54) FLUID COMPOSITIONS OF HYDRAULICALLY CONNECTED HYDROCARBON STREAMS

(71) Applicant: Saudi Arabian Oil Company, Dhahran (SA)

(72) Inventors: Hassan W. Al Hashim, Ad Dammam (SA); Bander Al Quaimi, Dhahran (SA); Abdulaziz Aldossary, Dhahran (SA)

(21) Appl. No.: 18/186,717

(22) Filed: Mar. 20, 2023

(51) Int. Cl. G06F 30/27

(52) U.S. Cl. CPC G06F 30/27

(57) ABSTRACT

Disclosed are methods, systems, and computer-readable medium to perform operations including: receiving input data comprising: (i) production data from a plurality of hydraulically connected wells, and (ii) measured pressure, volume, temperature (PVT) data for a subset of the plurality of hydraulically connected wells, wherein the measured PVT data comprises gas samples and oil samples; generating, using a radial based four-dimensional model, simulated PVT data for the plurality of hydraulically connected wells not in the subset; determining, based on the simulated PVT data, respective fluid compositions for the plurality of hydraulically connected wells; aggregating, based on one or more factors, the respective fluid compositions into an aggregated composition; and flashing the aggregated composition to a desired pressure and temperature.

### TECHNICAL FIELD

This description relates to methods and systems for calculating fluid compositions of hydrocarbon streams.

### BACKGROUND

Oil and gas companies rely on computer models to estimate information regarding hydrocarbon reservoirs, such as volumes of the reservoir. One such model is a fully compositional model that takes into account many components, such as different hydrocarbons, water, and the like. Compositional models further account for compositional variation with depth in the reservoir. Although highly accurate, calculations using compositional models are computationally expensive and may take many hours to complete (e.g., on the order of tens of hours).

### SUMMARY

This disclosure is directed to methods and systems for using artificial intelligence to predict multi-phase fluid compositions from streams that are hydraulically connected in a network. The methods and systems use individual wells' subsurface Pressure Volume Temperature (PVT) data to map fluid compositions and properties in different locations. The methods and systems also aggregate the impact of the fluid compositions based on the production contribution of the fluid compositions to the overall system. The methods and systems provide predicted compositions for each well stream. The methods and systems also provide a fractional composition for each well stream in comparison to an overall fluid stream (in which all fluids are mixed prior to entering the processing facility).

One aspect of the subject matter described in this specification may be embodied in a method that involves receiving input data including: (i) production data from a plurality of hydraulically connected wells, and (ii) measured pressure, volume, temperature (PVT) data for a subset of the plurality of hydraulically connected wells, where the measured PVT data includes gas samples and oil samples; generating, using a radial based four-dimensional model, simulated PVT data for the plurality of hydraulically connected wells not in the subset; determining, based on the simulated PVT data, respective fluid compositions for the plurality of hydraulically connected wells; aggregating, based on one or more factors, the respective fluid compositions into an aggregated composition; and flashing the aggregated composition to a desired pressure and temperature.

The previously described implementation is implementable using a computer-implemented method; a non-transitory, computer-readable medium storing computer-readable instructions to perform the computer-implemented method; and a computer system including a computer memory interoperably coupled with a hardware processor configured to perform the computer-implemented method or the instructions stored on the non-transitory, computer-readable medium. These and other embodiments may each optionally include one or more of the following features.

In some implementations, the input data further includes operating times for the plurality of hydraulically connected wells, and aggregating, based on one or more factors, the respective fluid compositions into an aggregated composition involves applying to the respective compositions respective weights that correspond to the respective operating times.

In some implementations, the production data includes at least one of: respective daily oil production rates for the plurality of hydraulically connected wells or respective daily gas production rates for the plurality of hydraulically connected wells.

In some implementations, the PVT data includes composition data for the subset of the plurality of hydraulically connected wells.

In some implementations, the input data further includes deviation surveys and completion configurations of the plurality of hydraulically connected wells, and the method further involves detecting well placement based on the deviation surveys and the completion configurations.

In some implementations, determining, based on the simulated PVT data, the respective fluid compositions involves determining, for a first well of the plurality of hydraulically connected wells, whether the respective composition of the first well includes free gas.

In some implementations, determining whether the respective composition of the first well includes free gas involves determining, from the production data, a production gas-oil-ratio (GOR_{production}) for the first well; calculating, based on the simulated PVT data, a predicted GOR (GOR_{predicted}) for the first well; and determining whether GOR_{production}≤(1+tol)*GOR_{predicted}, where tol is a predetermined acceptable tolerance.

In some implementations, determining whether the respective composition of the first well includes free gas involves in response to determining that GOR_{production} is ≤ (1+tol)*GOR_{predicted}, determining that the respective composition of the first well does not include free gas; or in response to determining that GOR_{production} is not ≤(1+tol)*GOR_{predicted}, determining that the respective composition of the first well does includes free gas

The details of one or more embodiments of these systems and methods are set forth in the accompanying drawings and description below. Other features, objects, and advantages of these systems and methods will be apparent from the description, drawings, and claims.

### BRIEF DESCRIPTION OF THE DRAWINGS

FIG. 1 illustrates an oil and gas processing network, according to some implementations.

FIG. 2 illustrates an example fluid composition prediction system, according to some implementations.

FIG. 3A and FIG. 3B illustrate example representations of multi-dimensional modeling, according to some implementations.

FIG. 4 illustrates an example fluid composition prediction workflow, according to some implementations.

FIG. 5 illustrates an example method, according to some implementations.

FIG. 6 is a block diagram of an example computer system, according to some implementations.

### DETAILED DESCRIPTION

The following detailed description describes systems and methods to using artificial intelligence to predict multi-phase fluid compositions from streams that are hydraulically connected in a network, and is presented to enable a person skilled in the art to make and use the disclosed subject matter in the context of one or more particular implementations. Various modifications, alterations, and permutations of the disclosed implementations can be made and will be readily apparent to those skilled in the art, and the general principles defined may be applied to other implementations and applications without departing from the scope of the disclosure. Thus, the present disclosure is not intended to be limited to the described or illustrated implementations, but is to be accorded the widest scope consistent with the principles and features disclosed.

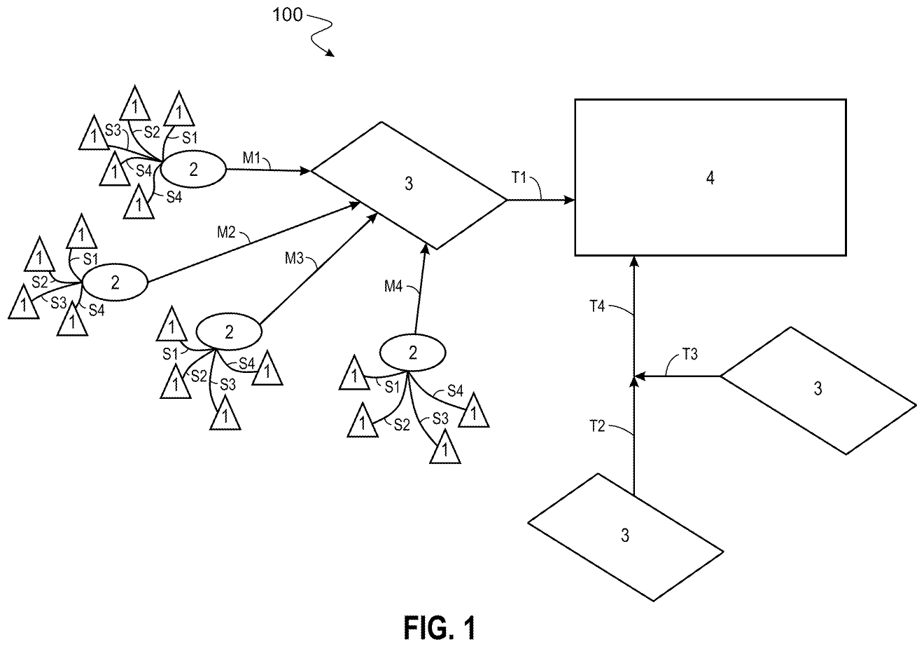

FIG. 1 illustrates an oil and gas processing network 100 that includes hydrocarbon wells (labelled as #1). The streams from the hydrocarbon wells (labelled as “S”) flow through pipelines from the wells to local gathering stations (e.g., local manifolds labelled as #2). The different streams from the local gathering stations combine into mixed streams (labelled as “T”) at gathering stations (labelled as “3”), before reaching a central processing facility (labelled as “4”). In the network 100, the production performance of the hydrocarbon wells is dynamic and changes over time, perhaps due to interventions that occur during the life of a well. This change in performance affects a particular well's contribution to the overall fluid feed to the central processing facility.

Optimum separation facility design is a function of multiple key parameters. One of these parameters is fluid composition. In existing systems, Pressure Volume Temperature (PVT) samples are manually collected from multiple key wells to construct a compositional model of the hydrocarbon streams. The quality of any compositional model depends on the sample size and accuracy of the data feed, which could potentially impact the design of the separation facility. Furthermore, upon constructing the facility, continuous manual sampling must be conducted to evaluate the stream feed at the central processing facility or any location of interest across the network.

This process is typically performed to ensure optimum separation conditions to yield the highest crude output. In existing systems, such sampling and evaluation is performed on-site, where a crew is mobilized to take pressurized samples across the network and send them back to a lab for compositional analysis at different conditions of pressures and temperatures. This process ensures yielding the most stock tank liquid while maintaining healthy reservoir conditions. However, in addition to being costly, this process is time-consuming and often requires significant logistics to facilitate taking pressurized samples from the streams to get their compositional properties.

This disclosure describes workflows that employ machine learning techniques to predict multi-phase fluid compositions of fluid streams that are hydraulically connected in a network. The workflows optimize the design parameters of central processing facilities and eliminate the need for physical sampling. The workflows map fluid compositions and properties from different locations based on a plurality of data, including location, depths, pressures, temperature, producing formation, and crude type. The workflows also aggregate the compositions based on the production contribution of the composition to the overall fluid stream (e.g., weighted based on each stream's contribution to the overall fluid stream). The workflows provide predicted compositions for each well stream as a fractional flow in comparison to the overall fluid stream.

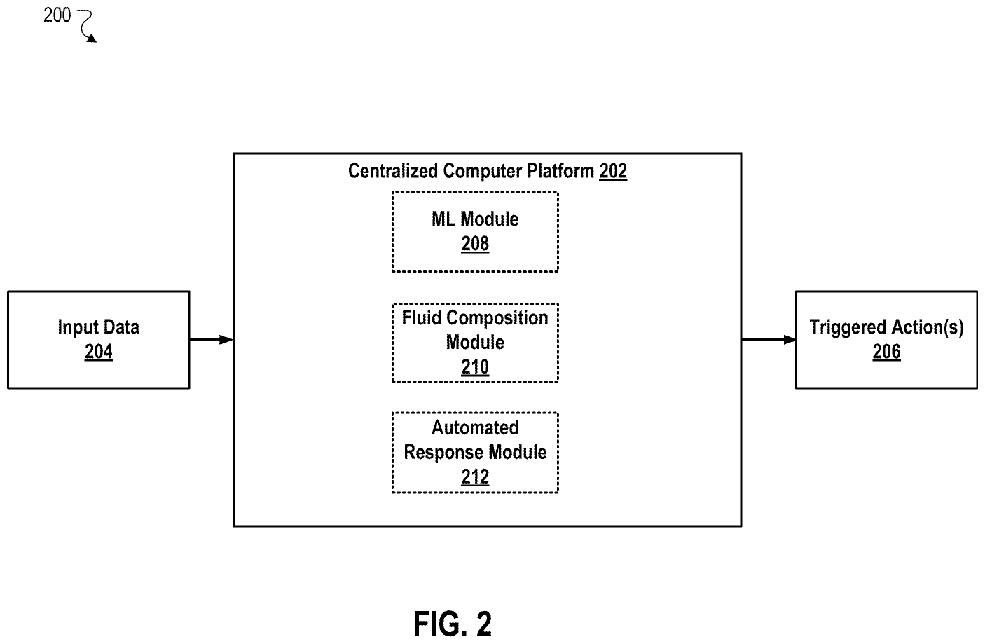

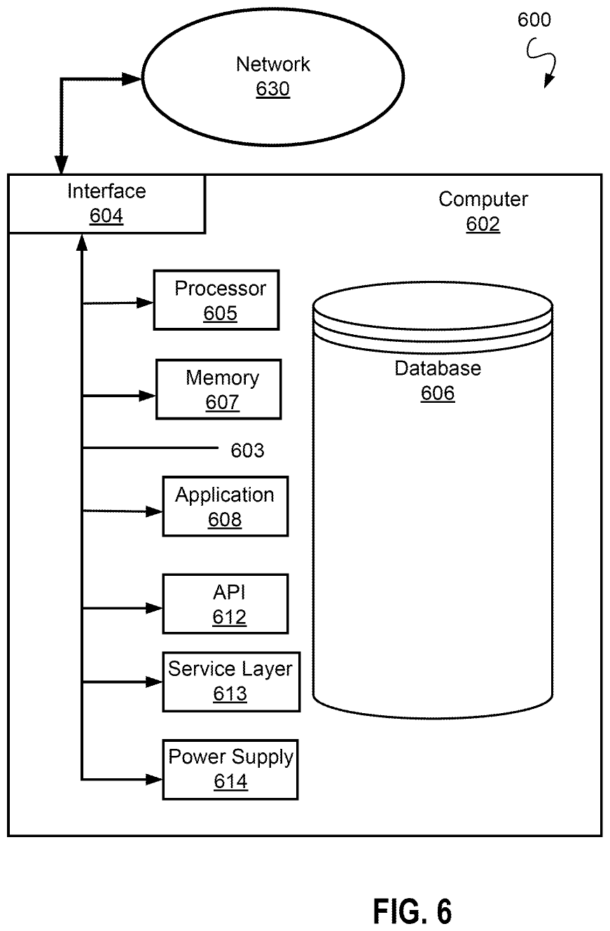

FIG. 2 illustrates a fluid composition prediction system 200, according to some implementations. The fluid composition prediction system 200 can be implemented in hardware, software, or both. A computing device representing the fluid composition prediction system 200 can be a special-purpose hardware integrated circuit that includes one or more processor microchips. The special-purpose circuitry can be used to implement machine learning algorithms corresponding to learning techniques that are implemented using, for example, neural networks, support vector machines, and/or multi-dimensional machine learning (e.g., based on radial basis functions). The computing device can also be included in a computer system 600, which is described later with reference to FIG. 6.

As shown in FIG. 2, the fluid composition prediction system 200 includes a centralized computer platform 202. The centralized computer platform 202 includes a machine learning module 208, a fluid composition module 210, and an automated response module 212. As described in more detail below, the centralized computer platform 202 receives input data 204. The machine learning module 208 uses the input data 204 to train a machine learning model for predicting fluid compositions in a network of hydraulically connected streams. The fluid composition module 210 uses the machine learning model to generate fluid composition predictions for the fluid streams in the network. Then, the automated response module 212 selects one or more actions to perform based on the fluid composition predictions and provides the one or more actions to relevant systems as triggered action(s) 206. Within examples, the triggered actions 206 include actions to shut in or adjust the rate of the wells to meet specific desired composition.

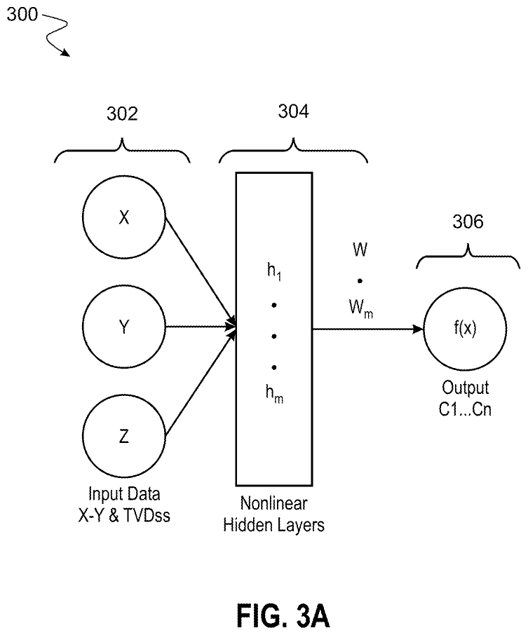

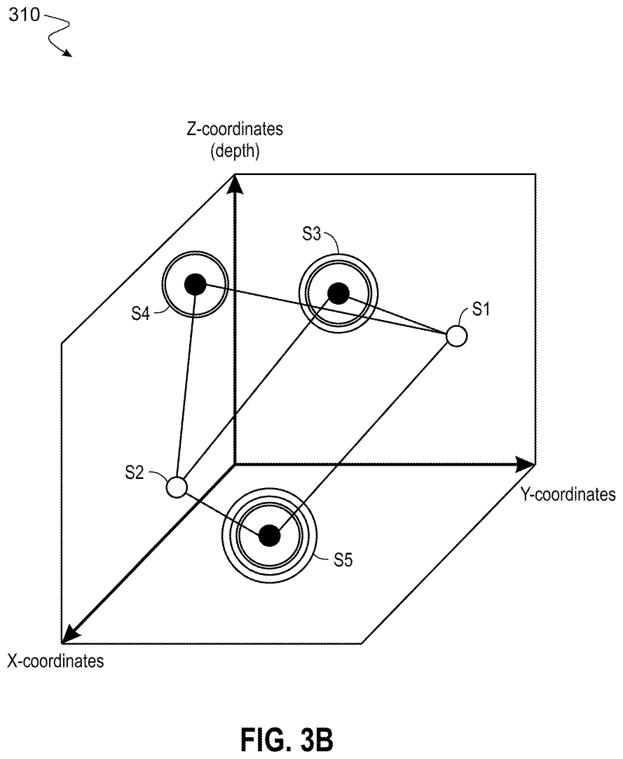

In some implementations, the machine learning module 208 generates a multi-dimensional machine learning model for obtaining fluid compositions. FIGS. 3A and 3B describe the multi-dimensional model in more detail.

FIGS. 3A, 3B illustrate example representations of multi-dimensional modeling, according to some implementations. Starting with FIG. 3A, the figure illustrates a representation of a multi-dimensional radial basis function 300. In an input later 302, one or more inputs to the multi-dimensional radial basis function 300 are selected based on one or more parameters related to the desired output. The one or more parameters can be selected based on a degree of influence that the parameter has over the desired output. In the context of fluid compositions, the one or more parameters include x-y coordinates, sample depths (z), pressures, temperatures, among other data, of the relevant wells. In the example of FIG. 3A, the input parameters include x-y coordinates and true vertical depth (TVD) of the relevant wells.

As shown in FIG. 3A, the input data is provided to a non-linear hidden layer 304. In some examples, the non-linear hidden layer 304 includes a non-linear estimator, such as a multi-quadratic estimator, a Gaussian estimator, or other types of estimators that can predict fluid compositions at each stream based on certain parameters. The prediction is performed based on the input parameters, which are weighted (wⱼ) and aggregated based the influence assigned to each parameter. In example, the prediction is performed using Equation [1]:

$$f ( x ) = {Σ}_{j = 1}^{m} ( {w}_{j} {h}_{j} ( x ) ) . \qquad [ 1 ]$$

In Equation [1], w is the weight, m is the number of radial basis functions used to yield an approximation of the desired parameters (compositions in this case), and h is a hidden layer. The weights (wⱼ) are determined based on the actual obtained data from streams.

Equation [1] provides an output 306. In an example, the output is the predicted composition, which can be a desired number of carbon compounds, e.g., C₁ (methane), C₂ (ethane), C₃ (propane), C₄ (butane), . . . C_{z}.

FIG. 3B illustrates an example radial basis function approach 310 that utilizes a non-linear estimator to predict the most probable compositions for each stream. In FIG. 3B, S1 and S2 are two streams of known compositions and the remaining points (e.g., S3, S4, S5) are other streams on the 3D vector space with unknown compositions that require estimation.

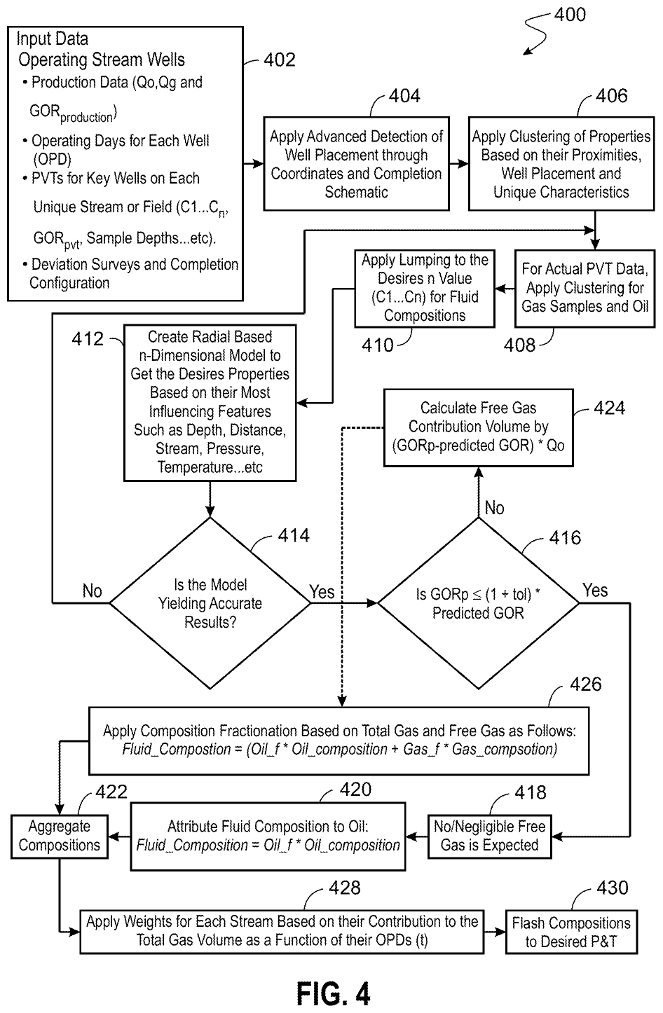

FIG. 4 illustrates a workflow 400 for predicting fluid compositions for a plurality of hydraulically connected well streams, according to some implementations. The plurality of hydraulically connected well streams flow from respective operating wells (e.g., the wells of FIG. 1). Note that the workflow 400 can be performed by the centralized computer platform 202 of FIG. 2 or by any other suitable system.

At step 402, the workflow 400 involves obtaining input data (e.g., input data 204). The input data includes information associated with the operating wells, such as coordinates (e.g., x-y-z position), production data, operating days (OPD), deviation surveys, and/or completion configurations. The production data can include a daily oil producing rate from each stream (Qo), a daily gas production rate from each stream (Qg), an actual production gas-oil-ratio (GOR_{production}) from each stream. Additionally, the input data includes information associated with a subset of the operating wells called key wells. More specifically, the information associated with the key wells can include PVT data for the one or more key wells. The PVT data includes measured fluid compositions (e.g., C₁, C₂, . . . C_{z}) and/or and gas-oil-ratios (GOR_{PVT}) from the streams of the one or more key wells.

At step 404, the workflow 400 involves applying advanced detection of well placement based on the well coordinates, the completion configurations, and/or the deviation surveys. This step uses the input data to generate a more accurate representation of the well positions. At step 406, the workflow 400 involves clustering the input data based on proximity, well placement, and/or other unique characteristics. In some examples, the input data is clustered based on a depth at which the sample is collected in the reservoir, a name of the reservoir or field, the type of the sample (i.e., oil or gas or both), and the field the sample was taken from. At step 408, the workflow 400 involves clustering the gas samples and oil samples in the PVT data (from the key wells) into respective clusters. At step 410, the workflow 400 involves applying lumping to the desired z values for fluid compositions (e.g., C₁, C₂, . . . C_{z}). Here, z denotes the number of components that are lumped to the z+ term. For example, C7+ includes all hydrocarbon components from C7 to the heavier components. This is done to reduce the dimensionality.

At step 412, the workflow 400 involves generating a radial based n-dimensional model for calculating the desired properties (e.g., fluid composition, PVT) of the streams. The radial based n-dimensional model calculated the desired properties based on the most influential features of the streams, such as depth, distance, stream, pressure, temperature, among other features. In one example, the radial based model is a four-dimensional model. Here, the four dimensions are depth, x and y coordinates, and reservoir. At step 414, the workflow 400 involves determining whether the model is yielding accurate results, e.g., by comparing the predictions generated by the model to known values (e.g., the PVT data of the key wells) and determining that the difference is less than a predetermined threshold. If the model is not yielding accurate results, the workflow 400 returns to step 408. Steps 408-412 are repeated until the model yields accurate results (e.g., greater than or equal to the predetermined threshold).

Once the model is yielding accurate results, the model can be used to generate simulated or predicted PVT data for the streams. After the simulated PVT data is generated, the workflow 400 calculates the fluid compositions of the streams. How the fluid composition is calculated for a stream, however, depends on whether there is a free gas contribution in that stream. Accordingly, the workflow 400 includes steps for determining whether there is a free gas contribution in each stream.

At step 416, the workflow 400 involves determining whether there is a free gas contribution in a stream. If there is a free gas contribution, the workflow 400 involves performing steps 424 and 426. However, if there is no free gas contribution, the workflow 400 involves performing steps 418 and 420. Then, partitioning can be applied to weigh and blend both the free gas and liquid stream, where the free gas is only accounted when it is present (otherwise it is 0).

At step 416, the workflow 400 involves determining whether there is a free gas contribution in a particular stream. In one example, the workflow 400 involves using the Equation [2] to determine whether there is a free gas contribution in a particular stream:

$${GOR}_{production} \leq ( 1 + tol ) * {GOR}_{predicted} . \qquad [ 2 ]$$

In Equation [2], GOR_{production} is the actual production gas-oil-ratio of a well and GOR_{predicted} is the predicted gas-oil-ratio calculated from the simulated PVT data of the well. A tolerance, tol, denotes an accepted tolerance from a prediction, and offsets any uncertainty in rate measurements or PVT data accuracy. The tolerance is predetermined and, in some examples, has a value between 0 and 1. GOR_{production} having a value greater than (1+tol)*GOR_{predicted} indicates that there is a free gas contribution. That is, the stream contains two phase hydrocarbon flow from the formation prior to reaching the saturation pressure along the well trajectory. In such scenarios, the workflow 400 moves to step 424 of calculating the free gas contribution.

In some implementations, the free gas contribution is estimated based on the difference between the actual production GOR and the predicted gas-oil-ratio calculated form the simulated PVT data. More specifically, at step 424, the workflow 400 involves calculating a free gas contribution using Equation [3]:

$$Free gas contribution = ( {GOR}_{production} - {GOR}_{predicted} ) * {Q}_{o} . \qquad [ 3 ]$$

Once the free gas contribution is calculated, the workflow 400 moves to step 426. At step 426, the workflow 400 involves applying composition fractionation based on a total gas and free gas using Equation [4]:

$$Fluid Composition = {Oil}_{f} * {Oil}_{Composition} + {Gas}_{f} * {Gas}_{composition} . \qquad [ 4 ]$$

In Equation [4], Oil_{f} is the fraction of the components coming from the oil rim based on the flow rates and Gas_{f} is the fraction of the components coming from the gas phase such as a gas cap. The sum of these to variables is always 1. Oil_{composition} is the oil rim/solution gas composition while the Gas_{composition} is the composition of the gas cap/free gas from the reservoir.

At step 422, the workflow 400 involves aggregating compositions. More specifically, step 422 involves aggregating the compositions based on their production contribution to the overall system (e.g., weighted based on each stream's contribution to the overall fluid stream). At step 428, the workflow 400 involves applying weights for each stream based on their contribution to the total gas volume as a function of their OPDs (i.e., time). The time function is based on the total liquid and gas volumes at a specific time step (i.e., daily, month, yearly, etc.). It is a function of the operating days, denoted by OPD of each stream in comparison to the total volumes going through the stream. At step 430, the workflow 400 involves flashing compositions to a desired pressure and temperature. That is, the outcome will be an aggregate fluid composition per each time step that can be extrapolated to any specific desired pressure and temperature (P&T).

The workflow 400 helps enhance the design of central processing facilities. Further, the workflow 400 optimizes and reduces the frequency of physical sampling. Additionally, the workflow 400 enables prediction of the molecular weight for optimum compressor operating efficiency. Furthermore, the workflow 400 maps fluid compositions and properties from different locations based on a multitude of data such as location, depths, pressures, temperature, producing formation and crude type. It also aggregates the compositions based on their production contribution to the overall system (i.e., weighted based on each stream's contribution to the overall fluid stream). Further, the workflow 400 utilizes time steps as a function of actual produced volumes at specific streams.

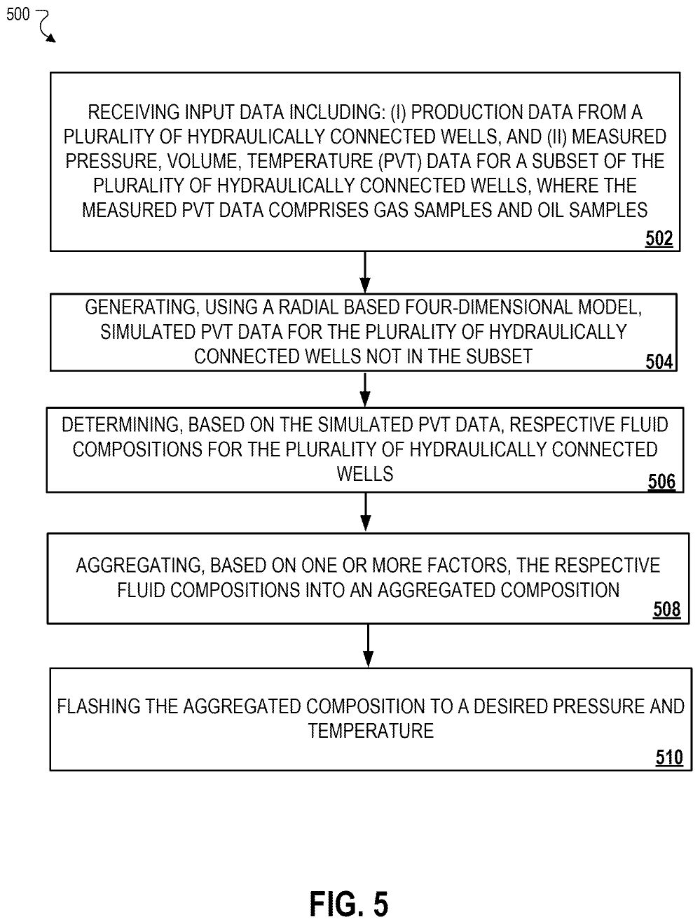

FIG. 5 illustrates a flowchart of an example method 500, according to some implementations. For clarity of presentation, the description that follows generally describes method 500 in the context of the other figures in this description. For example, method 500 can be performed by centralized computer platform 202 of FIG. 2. It will be understood that method 500 can be performed, for example, by any suitable system, environment, software, hardware, or a combination of systems, environments, software, and hardware, as appropriate. In some implementations, various steps of method 500 can be run in parallel, in combination, in loops, or in any order.

At step 502, the method 500 involves receiving input data including: (i) production data from a plurality of hydraulically connected wells, and (ii) measured pressure, volume, temperature (PVT) data for a subset of the plurality of hydraulically connected wells, where the measured PVT data includes gas samples and oil samples.

At step 504, the method 500 involves generating, using a radial based four-dimensional model, simulated PVT data for the plurality of hydraulically connected wells not in the subset.

At step 506, the method 500 involves determining, based on the simulated PVT data, respective fluid compositions for the plurality of hydraulically connected wells.

At step 508, the method 500 involves aggregating, based on one or more factors, the respective fluid compositions into an aggregated composition.

At step 510, the method 500 involves flashing the aggregated composition to a desired pressure and temperature.

In some implementations, the input data further includes operating times for the plurality of hydraulically connected wells, and aggregating, based on one or more factors, the respective fluid compositions into an aggregated composition involves applying to the respective compositions respective weights that correspond to the respective operating times.

In some implementations, the production data includes at least one of: respective daily oil production rates for the plurality of hydraulically connected wells or respective daily gas production rates for the plurality of hydraulically connected wells.

In some implementations, the PVT data includes composition data for the subset of the plurality of hydraulically connected wells.

In some implementations, the input data further includes deviation surveys and completion configurations of the plurality of hydraulically connected wells, and the method further involves detecting well placement based on the deviation surveys and the completion configurations.

In some implementations, determining, based on the simulated PVT data, the respective fluid compositions involves determining, for a first well of the plurality of hydraulically connected wells, whether the respective composition of the first well includes free gas.

In some implementations, determining whether the respective composition of the first well includes free gas involves determining, from the production data, a production gas-oil-ratio (GOR_{production}) for the first well; calculating, based on the simulated PVT data, a predicted GOR (GOR_{predicted}) for the first well; and determining whether GOR_{production}≤(1+tol)*GOR_{predicted}, where tol is a predetermined acceptable tolerance.

In some implementations, determining whether the respective composition of the first well includes free gas involves in response to determining that GOR_{production} is ≤(1+tol)*GOR_{predicted}, determining that the respective composition of the first well does not include free gas; or in response to determining that GOR_{production} is not ≤(1+tol)*GOR_{predicted}, determining that the respective composition of the first well does includes free gas.

FIG. 6 is a block diagram of an example computer system 600 that can be used to provide computational functionalities associated with described algorithms, methods, functions, processes, flows, and procedures, according to some implementations of the present disclosure. In some implementations, the centralized computer platform 202 can be the computer system 600, include the computer system 600, or the centralized computer platform 202 can communicate with the computer system 600.

The illustrated computer 602 is intended to encompass any computing device such as a server, a desktop computer, an embedded computer, a laptop/notebook computer, a wireless data port, a smart phone, a personal data assistant (PDA), a tablet computing device, or one or more processors within these devices, including physical instances, virtual instances, or both. The computer 602 can include input devices such as keypads, keyboards, and touch screens that can accept user information. Also, the computer 602 can include output devices that can convey information associated with the operation of the computer 602. The information can include digital data, visual data, audio information, or a combination of information. The information can be presented in a graphical user interface (UI) (or GUI). In some implementations, the inputs and outputs include display ports (such as DVI-I+2x display ports), USB 3.0, GbE ports, isolated DI/O, SATA-III (6.0 Gb/s) ports, mPCIe slots, a combination of these, or other ports. In instances of an edge gateway, the computer 602 can include a Smart Embedded Management Agent (SEMA), such as a built-in ADLINK SEMA 2.2, and a video sync technology, such as Quick Sync Video technology supported by ADLINK MSDK+. In some examples, the computer 602 can include the MXE-5400 Series processor-based fanless embedded computer by ADLINK, though the computer 602 can take other forms or include other components.

The computer 602 can serve in a role as a client, a network component, a server, a database, a persistency, or components of a computer system for performing the subject matter described in the present disclosure. The illustrated computer 602 is communicably coupled with a network 630. In some implementations, one or more components of the computer 602 can be configured to operate within different environments, including cloud-computing-based environments, local environments, global environments, and combinations of environments.

At a high level, the computer 602 is an electronic computing device operable to receive, transmit, process, store, and manage data and information associated with the described subject matter. According to some implementations, the computer 602 can also include, or be communicably coupled with, an application server, an email server, a web server, a caching server, a streaming data server, or a combination of servers.

The computer 602 can receive requests over network 630 from a client application (for example, executing on another computer 602). The computer 602 can respond to the received requests by processing the received requests using software applications. Requests can also be sent to the computer 602 from internal users (for example, from a command console), external (or third) parties, automated applications, entities, individuals, systems, and computers.

Each of the components of the computer 602 can communicate using a system bus 603. In some implementations, any or all of the components of the computer 602, including hardware or software components, can interface with each other or the interface 604 (or a combination of both), over the system bus. Interfaces can use an application programming interface (API) 612, a service layer 613, or a combination of the API 612 and service layer 613. The API 612 can include specifications for routines, data structures, and object classes. The API 612 can be either computer-language independent or dependent. The API 612 can refer to a complete interface, a single function, or a set of APIs 612.

The service layer 613 can provide software services to the computer 602 and other components (whether illustrated or not) that are communicably coupled to the computer 602. The functionality of the computer 602 can be accessible for all service consumers using this service layer 613. Software services, such as those provided by the service layer 613, can provide reusable, defined functionalities through a defined interface. For example, the interface can be software written in JAVA, C++, or a language providing data in extensible markup language (XML) format. While illustrated as an integrated component of the computer 602, in alternative implementations, the API 612 or the service layer 613 can be stand-alone components in relation to other components of the computer 602 and other components communicably coupled to the computer 602. Moreover, any or all parts of the API 612 or the service layer 613 can be implemented as child or sub-modules of another software module, enterprise application, or hardware module without departing from the scope of the present disclosure.

The computer 602 can include an interface 604. Although illustrated as a single interface 604 in FIG. 6, two or more interfaces 604 can be used according to particular needs, desires, or particular implementations of the computer 602 and the described functionality. The interface 604 can be used by the computer 602 for communicating with other systems that are connected to the network 630 (whether illustrated or not) in a distributed environment. Generally, the interface 604 can include, or be implemented using, logic encoded in software or hardware (or a combination of software and hardware) operable to communicate with the network 630. More specifically, the interface 604 can include software supporting one or more communication protocols associated with communications. As such, the network 630 or the interface's hardware can be operable to communicate physical signals within and outside of the illustrated computer 602.

The computer 602 includes a processor 605. Although illustrated as a single processor 605 in FIG. 6, two or more processors 605 can be used according to particular needs, desires, or particular implementations of the computer 602 and the described functionality. Generally, the processor 605 can execute instructions and manipulate data to perform the operations of the computer 602, including operations using algorithms, methods, functions, processes, flows, and procedures as described in the present disclosure.

The computer 602 can also include a database 606 that can hold data for the computer 602 and other components connected to the network 630 (whether illustrated or not). For example, database 606 can be an in-memory, conventional, or a database storing data consistent with the present disclosure. In some implementations, the database 606 can be a combination of two or more different database types (for example, hybrid in-memory and conventional databases) according to particular needs, desires, or particular implementations of the computer 602 and the described functionality. Although illustrated as a single database 606 in FIG. 6, two or more databases (of the same, different, or combination of types) can be used according to particular needs, desires, or particular implementations of the computer 602 and the described functionality. While database 606 is illustrated as an internal component of the computer 602, in alternative implementations, database 606 can be external to the computer 602.

The computer 602 also includes a memory 607 that can hold data for the computer 602 or a combination of components connected to the network 630 (whether illustrated or not). Memory 607 can store any data consistent with the present disclosure. In some implementations, memory 607 can be a combination of two or more different types of memory (for example, a combination of semiconductor and magnetic storage) according to particular needs, desires, or particular implementations of the computer 602 and the described functionality. Although illustrated as a single memory 607 in FIG. 6, two or more memories 607 (of the same, different, or combination of types) can be used according to particular needs, desires, or particular implementations of the computer 602 and the described functionality. While memory 607 is illustrated as an internal component of the computer 602, in alternative implementations, memory 607 can be external to the computer 602.

An application 608 can be an algorithmic software engine providing functionality according to particular needs, desires, or particular implementations of the computer 602 and the described functionality. For example, an application 608 can serve as one or more components, modules, or applications 608. Multiple applications 608 can be implemented on the computer 602. Each application 608 can be internal or external to the computer 602.

The computer 602 can also include a power supply 614. The power supply 614 can include a rechargeable or non-rechargeable battery that can be configured to be either user- or non-user-replaceable. In some implementations, the power supply 614 can include power-conversion and management circuits, including recharging, standby, and power management functionalities. In some implementations, the power-supply 614 can include a power plug to allow the computer 602 to be plugged into a wall socket or a power source to, for example, power the computer 602 or recharge a rechargeable battery.

There can be any number of computers 602 associated with, or external to, a computer system including computer 602, with each computer 602 communicating over network 630. Further, the terms “client”, “user”, and other appropriate terminology can be used interchangeably without departing from the scope of the present disclosure. Moreover, the present disclosure contemplates that many users can use one computer 602 and one user can use multiple computers 602.

Implementations of the subject matter and the functional operations described in this specification can be implemented in digital electronic circuitry, in tangibly embodied computer software or firmware; in computer hardware, including the structures disclosed in this specification and their structural equivalents; or in combinations of one or more of them. Software implementations of the described subject matter can be implemented as one or more computer programs. Each computer program can include one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal. For example, the signal can be a machine-generated electrical, optical, or electromagnetic signal that is generated to encode information for transmission to a suitable receiver apparatus for execution by a data processing apparatus. The computer-storage medium can be a machine-readable storage device, a machine-readable storage substrate, a random or serial access memory device, or a combination of computer-storage mediums.

The terms “data processing apparatus”, “computer”, and “electronic computer device” (or equivalent as understood by one of ordinary skill in the art) refer to data processing hardware. For example, a data processing apparatus can encompass all kinds of apparatuses, devices, and machines for processing data, including by way of example, a programmable processor, a computer, or multiple processors or computers. The apparatus can also include special purpose logic circuitry including, for example, a central processing unit (CPU), a field programmable gate array (FPGA), or an application specific integrated circuit (ASIC). In some implementations, the data processing apparatus or special purpose logic circuitry (or a combination of the data processing apparatus and special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, for example, Linux, Unix, Windows, Mac OS, Android, or iOS.

A computer program, which can also be referred to or described as a program, software, a software application, a module, a software module, a script, or code can be written in any form of programming language. Programming languages can include, for example, compiled languages, interpreted languages, declarative languages, or procedural languages. Programs can be deployed in any form, including as stand-alone programs, modules, components, subroutines, or units for use in a computing environment. A computer program can, but need not, correspond to a file in a file system. A program can be stored in a portion of a file that holds other programs or data, for example, one or more scripts stored in a markup language document; in a single file dedicated to the program in question; or in multiple coordinated files storing one or more modules, sub programs, or portions of code. A computer program can be deployed for execution on one computer or on multiple computers that are located, for example, at one site or distributed across multiple sites that are interconnected by a communication network. While portions of the programs illustrated in the various figures may be shown as individual modules that implement the various features and functionality through various objects, methods, or processes; the programs can instead include a number of sub-modules, third-party services, components, and libraries. Conversely, the features and functionality of various components can be combined into single components as appropriate. Thresholds used to make computational determinations can be statically, dynamically, or both statically and dynamically determined.

The methods, processes, or logic flows described in this specification can be performed by one or more programmable computers executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computers suitable for the execution of a computer program can be based on one or more of general and special purpose microprocessors and other kinds of CPUs. The elements of a computer are a CPU for performing or executing instructions and one or more memory devices for storing instructions and data. Generally, a CPU can receive instructions and data from (and write data to) a memory. A computer can also include, or be operatively coupled to, one or more mass storage devices for storing data. In some implementations, a computer can receive data from, and transfer data to, the mass storage devices including, for example, magnetic, magneto optical disks, or optical disks. Moreover, a computer can be embedded in another device, for example, a mobile telephone, a personal digital assistant (PDA), a mobile audio or video player, a game console, a global positioning system (GPS) receiver, or a portable storage device such as a universal serial bus (USB) flash drive.

Computer readable media (transitory or non-transitory, as appropriate) suitable for storing computer program instructions and data can include all forms of permanent/non-permanent and volatile/non-volatile memory, media, and memory devices. Computer readable media can include, for example, semiconductor memory devices such as random access memory (RAM), read only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer readable media can also include, for example, magnetic devices such as tape, cartridges, cassettes, and internal/removable disks. Computer readable media can also include magneto optical disks, optical memory devices, and technologies including, for example, digital video disc (DVD), CD ROM, DVD+/−R, DVD-RAM, DVD-ROM, HD-DVD, and BLURAY. The memory can store various objects or data, including caches, classes, frameworks, applications, modules, backup data, jobs, web pages, web page templates, data structures, database tables, repositories, and dynamic information. Types of objects and data stored in memory can include parameters, variables, algorithms, instructions, rules, constraints, and references. Additionally, the memory can include logs, policies, security or access data, and reporting files. The processor and the memory can be supplemented by, or incorporated in, special purpose logic circuitry.

Implementations of the subject matter described in the present disclosure can be implemented on a computer having a display device for providing interaction with a user, including displaying information to (and receiving input from) the user. Types of display devices can include, for example, a cathode ray tube (CRT), a liquid crystal display (LCD), a light-emitting diode (LED), or a plasma monitor. Display devices can include a keyboard and pointing devices including, for example, a mouse, a trackball, or a trackpad. User input can also be provided to the computer through the use of a touchscreen, such as a tablet computer surface with pressure sensitivity or a multi-touch screen using capacitive or electric sensing. Other kinds of devices can be used to provide for interaction with a user, including to receive user feedback, for example, sensory feedback including visual feedback, auditory feedback, or tactile feedback. Input from the user can be received in the form of acoustic, speech, or tactile input. In addition, a computer can interact with a user by sending documents to, and receiving documents from, a device that is used by the user. For example, the computer can send web pages to a web browser on a user's client device in response to requests received from the web browser.

The term “graphical user interface,” or “GUI,” can be used in the singular or the plural to describe one or more graphical user interfaces and each of the displays of a particular graphical user interface. Therefore, a GUI can represent any graphical user interface, including, but not limited to, a web browser, a touch screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back end component, for example, as a data server, or that includes a middleware component, for example, an application server. Moreover, the computing system can include a front-end component, for example, a client computer having one or both of a graphical user interface or a Web browser through which a user can interact with the computer. The components of the system can be interconnected by any form or medium of wireline or wireless digital data communication (or a combination of data communication) in a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) (for example, using 802.11 a/b/g/n or 802.20 or a combination of protocols), all or a portion of the Internet, or any other communication system or systems at one or more locations (or a combination of communication networks). The network can communicate with, for example, Internet Protocol (IP) packets, frame relay frames, asynchronous transfer mode (ATM) cells, voice, video, data, or a combination of communication types between network addresses.

The computing system can include clients and servers. A client and server can generally be remote from each other and can typically interact through a communication network. The relationship of client and server can arise by virtue of computer programs running on the respective computers and having a client-server relationship.

Cluster file systems can be any file system type accessible from multiple servers for read and update. Locking or consistency tracking may not be necessary since the locking of exchange file system can be done at application layer. Furthermore, Unicode data files can be different from non-Unicode data files.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, or in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations; and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

1. A method comprising:
receiving input data comprising: (i) production data from a plurality of hydraulically connected wells, and (ii) measured pressure, volume, temperature (PVT) data for a subset of the plurality of hydraulically connected wells, wherein the measured PVT data comprises gas samples and oil samples;
generating, using a radial based four-dimensional model, simulated PVT data for the plurality of hydraulically connected wells not in the subset;
determining, based on the simulated PVT data, respective fluid compositions for the plurality of hydraulically connected wells;
aggregating, based on one or more factors, the respective fluid compositions into an aggregated composition; and
flashing the aggregated composition to a desired pressure and temperature.

2. The method of claim 1, wherein the input data further comprises operating times for the plurality of hydraulically connected wells, and wherein aggregating, based on one or more factors, the respective fluid compositions into an aggregated composition comprises:
applying to the respective compositions respective weights that correspond to the respective operating times.

3. The method of claim 1, wherein the production data comprises at least one of: respective daily oil production rates for the plurality of hydraulically connected wells or respective daily gas production rates for the plurality of hydraulically connected wells.

4. The method of claim 1, wherein the PVT data comprises composition data for the subset of the plurality of hydraulically connected wells.

5. The method of claim 1, wherein the input data further comprises deviation surveys and completion configurations of the plurality of hydraulically connected wells, and wherein the method further comprises:
detecting well placement based on the deviation surveys and the completion configurations.

6. The method of claim 1, wherein determining, based on the simulated PVT data, the respective fluid compositions comprises:
determining, for a first well of the plurality of hydraulically connected wells, whether the respective composition of the first well includes free gas.

7. The method of claim 6, wherein determining whether the respective composition of the first well includes free gas comprises:
determining, from the production data, a production gas-oil-ratio (GOR_{production}) for the first well;
calculating, based on the simulated PVT data, a predicted GOR (GOR_{predicted}) for the first well; and
determining whether GOR_{production}≤(1+tol)*GOR_{predicted}, wherein tol is a predetermined acceptable tolerance.

8. The method of claim 7, wherein determining whether the respective composition of the first well includes free gas comprises:
in response to determining that GOR_{production} is ≤(1+tol)*GOR_{predicted}, determining that the respective composition of the first well does not include free gas; or
in response to determining that GOR_{production} is not ≤(1+tol)*GOR_{predicted}, determining that the respective composition of the first well does includes free gas.

9. A non-transitory computer storage medium encoded with instructions that, when executed by one or more computers, cause the one or more computers to perform operations comprising:
receiving input data comprising: (i) production data from a plurality of hydraulically connected wells, and (ii) measured pressure, volume, temperature (PVT) data for a subset of the plurality of hydraulically connected wells, wherein the measured PVT data comprises gas samples and oil samples;
generating, using a radial based four-dimensional model, simulated PVT data for the plurality of hydraulically connected wells not in the subset;
determining, based on the simulated PVT data, respective fluid compositions for the plurality of hydraulically connected wells;
aggregating, based on one or more factors, the respective fluid compositions into an aggregated composition; and
flashing the aggregated composition to a desired pressure and temperature.

10. The non-transitory computer storage medium of claim 9, wherein the input data further comprises operating times for the plurality of hydraulically connected wells, and wherein aggregating, based on one or more factors, the respective fluid compositions into an aggregated composition comprises:
applying to the respective compositions respective weights that correspond to the respective operating times.

11. The non-transitory computer storage medium of claim 9, wherein the production data comprises at least one of: respective daily oil production rates for the plurality of hydraulically connected wells or respective daily gas production rates for the plurality of hydraulically connected wells.

12. The non-transitory computer storage medium of claim 9, wherein the PVT data comprises composition data for the subset of the plurality of hydraulically connected wells.

13. The non-transitory computer storage medium of claim 9, wherein the input data further comprises deviation surveys and completion configurations of the plurality of hydraulically connected wells, and wherein the method further comprises:
detecting well placement based on the deviation surveys and the completion configurations.

14. The non-transitory computer storage medium of claim 9, wherein determining, based on the simulated PVT data, the respective fluid compositions comprises:
determining, for a first well of the plurality of hydraulically connected wells, whether the respective composition of the first well includes free gas.

15. The non-transitory computer storage medium of claim 14, wherein determining whether the respective composition of the first well includes free gas comprises:
determining, from the production data, a production gas-oil-ratio (GOR_{production}) for the first well;
calculating, based on the simulated PVT data, a predicted GOR (GOR_{predicted}) for the first well; and
determining whether GOR_{production}≤(1+tol)*GOR_{predicted}, wherein tol is a predetermined acceptable tolerance.
